(19) United States
(12) Patent Application Publication
(10) Pub. No.: US 2008/0254617 A1
(43) Pub. Date: Oct. 16, 2008

(54) Void-free contact plug

(76) Inventors: Olubunmi O. Adetutu, Austin, TX (US); Elsie D. Banks, Austin, TX (US); Jeffrey W. Thomas, Pflugerville, TX (US)

Correspondence Address: HAMILTON & TERRILE, LLP, P.O. BOX 203518, AUSTIN, TX, 78720, US

(21) Appl. No.: 11/733,519

(22) Filed: Apr. 10, 2007

(51) Int. Cl. H01L 21/4763

(52) U.S. Cl. 438/643; 257/E21.495

(57) ABSTRACT

A semiconductor device manufacturing process for forming a contact plug includes sequentially depositing a titanium or tantalum contact layer (30), a titanium nitride barrier layer (40), and a tungsten seed layer (50) in a contact opening (24). The contact hole (24) is then filled up from a bottom surface of the contact opening by electroplating a copper layer (60) so that no voids are formed in the contact opening (24). Any excess metal is removed with a CMP process to form the contact plugs (70), where the CMP process may also used to thin or remove one or more of the contact/seed/barrier layers (30, 40, 50).

### BACKGROUND OF THE INVENTION

1. Field of the Invention

The present invention is directed in general to the field of semiconductor devices. In one aspect, the present invention relates to the formation of contact plugs.

2. Description of the Related Art

Semiconductor devices typically include device components (such as transistors and capacitors) that are formed on or in a substrate as part of the front end of line (FEOL) processing. In addition, interconnect features (such as contacts, metal lines and vias) that connect the device components to the outside world are included as part of the back end of line (BEOL) integration process whereby one or more dielectric layers are formed in and between the interconnect features for purposes of electrically isolating the interconnect features and device components. Until recently, conventional metal deposition processes would fill the contact plug openings by depositing a layer of tungsten or copper over one or more underlying sub-layers. However, as the aspect ratios have increased with smaller sized devices, such as non-volatile memory (NVM) devices, the existing processes for forming the contact plug often result in the formation of contact plugs that have voids or cores formed therein. The voids result from the fact that conventional deposition processes do not form the metal layer uniformly inside the contact plug opening, but instead form the metal (e.g., tungsten) more thickly on the upper regions of the contact plug opening, leaving a void or core in the lower region. An example of such a conventional plug formation process is illustrated in FIG. 1, which depicts a semiconductor device 19 in which a contact plug is formed in an opening 12 of a dielectric layer 11 over a device structure 10 (such as a gate or source/drain) by depositing a layer of tungsten 15 over one or more sub-layers 13, 14 (e.g., titanium and TiN) such that the tungsten forms more thickly at the top of the contact opening 12, thereby forming a void region 16 in the tungsten. The presence of voids in contact plugs can drastically increase contact resistance, can trap CMP slurry materials from subsequent processing steps and can substantially reduce device yield. Prior attempts to eliminate voids by conformally depositing tungsten with an atomic layer deposition (ALD) process are not manufacturable since an ALD processes requires too much time to provide the required thickness to fill the contact plug. Other attempts to eliminate voids have included electroplating different conductive material (e.g., copper) over one or more barrier layer materials, such as metal nitride (e.g., tantalum nitride). However, these attempts require additional processing steps and have reduced electrical performance (such as higher contact resistance). In addition, there are other drawbacks associated with prior attempts to form contact plugs with copper, including diffusion of copper into the active region or interlayer dielectric and/or impaired interlayer adhesion between the copper and the underlying layer(s).

Accordingly, a need exists for an improved process for fabricating contact plugs that are void-free. In addition, there is a need for a void-free contact plug that can be effectively, efficiently and reliably integrated into the front end of line process. There is also a need for an improved contact plug formation process that will lower contact resistance and reduce copper diffusion. There is also a need for an improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 is a partial cross-sectional view of a semiconductor device in which is formed a contact plug having a void;

FIG. 2 is a partial cross-sectional view of a semiconductor device in which a contact opening is formed in an interlevel dielectric layer to expose a device component;

FIG. 3 illustrates processing subsequent to FIG. 2 after deposition of a titanium layer into the contact opening;

FIG. 4 illustrates processing subsequent to FIG. 3 after deposition of a titanium nitride barrier layer into the contact opening;

FIG. 5 illustrates processing subsequent to FIG. 4 after deposition of a tungsten layer into the contact opening;

FIG. 6 illustrates processing subsequent to FIG. 5 after the contact opening is filled by electroplating a contact metal plug material onto the tungsten layer;

FIG. 7 illustrates processing subsequent to FIG. 6 after removal of the excess contact metal and at least part of one or more of the underlying barrier layers with a chemical mechanical polish step; and

FIG. 8 is a flow diagram illustrating a process for forming a void-free contact plug.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A method and apparatus are described for forming a semiconductor device that has a void-free contact plug by sequentially depositing in a contact plug opening a contact layer (e.g., Ti) and one or more diffusion barrier layers, including a layer of tungsten, before filling the plug with electroplated copper. In a selected embodiment, the initial contact layer is formed by depositing titanium, which acts to reduce the formation of native oxide on an underlying silicide layer. By depositing a layer of titanium nitride over the contact layer, a fluorine barrier is formed to prevent a volatile fluorine reaction from occurring during a subsequent formation of a tungsten barrier layer. The titanium nitride may also provide a copper diffusion barrier function for the contact plug to prevent subsequently formed copper from diffusing through the titanium nitride layer. By depositing a thin tungsten barrier layer, a seed layer is formed for the subsequent copper electroplating step. In various embodiments, the tungsten barrier layer may be formed with an amorphous or small grain structure to act as a copper diffusion barrier to prevent subsequently-formed copper from diffusing through to the underlying layer(s). For example, the tungsten barrier layer may be formed with an amorphous or small grain structure by using a silicon source decomposition process (e.g., WF₆+SiH₄). When the barrier layer is formed with an amorphous material having a small grain nanocrystalline structure (e.g., grains smaller than approximately 50 Angstroms), the crystalline structure reduces or prevents the diffusion of subsequently deposited metal ions, as compared to the diffusion barrier properties of large grain materials which are not as effective in prevention diffusing of metal ions through to the underlying layer(s). After polishing the copper and barrier layer(s), any desired back end of line processing, such as standard CMOS BEOL processing, may be used to complete the device. With the disclosed methodology and apparatus, plug voids are reduced or eliminated, thereby increasing manufacturing yield, particularly for NVM products with aggressive contact plug aspect ratio, though the disclosed techniques can be used for any product or technology where voids in the plug limits yield.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, it is noted that, throughout this detailed description, certain layers of materials will be deposited and removed to form the depicted semiconductor structures. Where the specific procedures for depositing or removing such layers are not detailed below, conventional techniques to one skilled in the art for depositing, removing or otherwise forming such layers at appropriate thicknesses shall be intended. Such details are well known and not considered necessary to teach one skilled in the art of how to make or use the present invention. In addition, selected aspects are depicted with reference to simplified cross sectional drawings of a semiconductor device without including every device feature or geometry in order to avoid limiting or obscuring the present invention. Such descriptions and representations are used by those skilled in the art to describe and convey the substance of their work to others skilled in the art. It is also noted that, throughout this detailed description, certain elements in the figures are illustrated for simplicity and clarity and have not necessarily been drawn to scale. For example, the dimensions of some of the elements in the figures may be exaggerated relative to other elements to help improve the understanding of the embodiments of the present invention.

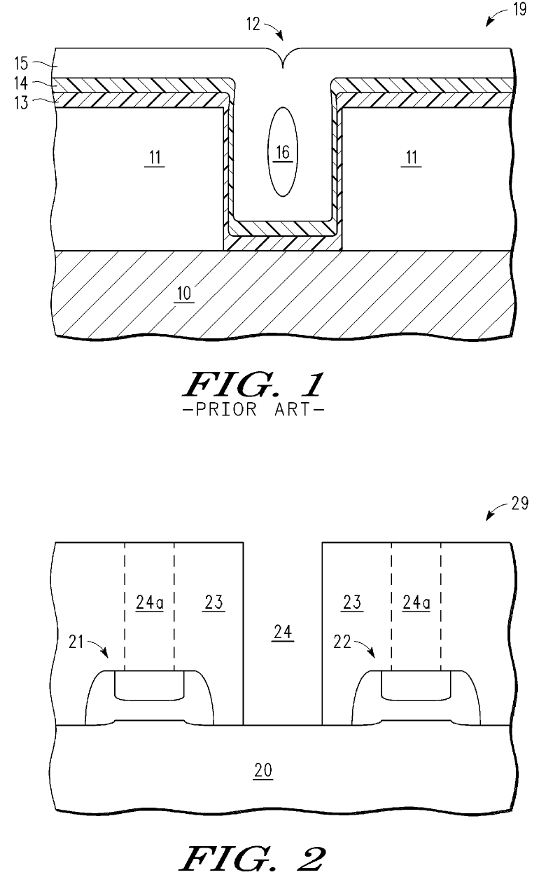

Beginning with FIG. 2, a partial cross-sectional view is shown of a semiconductor device 29 in which a contact opening 24 is formed in an inter-level dielectric layer (ILD) 23 formed over a substrate 20 and one or more device components 21, 22. Depending on the type of transistor devices 21, 22 being fabricated, the substrate 20 may be implemented as a bulk silicon substrate, single crystalline silicon (doped or undoped), or any semiconductor material including, for example, Si, SiC, SiGe, SiGeC, Ge, GaAs, InAs, InP as well as other Group III-IV compound semiconductors or any combination thereof, and may optionally be formed as the bulk handling wafer. In addition, the substrate 20 may be implemented as the top semiconductor layer of a semiconductor on-insulator (SOI) structure or a hybrid substrate comprised of bulk and/or SOI regions with differing crystal orientation.

Using any desired front end of line processing, each of the device components 21, 22 may be formed as a MOSFET transistor, double gate fully depleted semiconductor-on-insulator (FDSOI) transistor, NVM transistor, capacitor, diode or any other integrated circuit component formed on the substrate 11. In the simplified device example illustrated in FIG. 2, a first device component 21 is a MOSFET transistor which is formed in part from a gate electrode layer that is formed over and insulated from a channel region in the substrate 20 by a gate dielectric and that has formed thereon one or more sidewall spacers that are used during implantation of source/drain regions in the substrate 20. The second device component 22 may also be a MOSFET transistor, or may be another component, such as a non-volatile memory (NVM) device having a channel region over which is formed a first insulating layer or tunnel dielectric and an NVM gate stack which includes a floating gate, a control dielectric layer formed over the floating gate, and a control gate formed over the control dielectric layer (not separately shown). As will be appreciated, there are other types of NVM devices besides floating gate devices, including nanocluster devices and SONOS (silicon-oxide-nitride-oxide-silicon) devices.

Regardless of the specific type of device components 21, 22 formed on the substrate 20, the components are electrically isolated by blanket depositing a conformal or near conformal etch stop layer (not shown) and one or more pre-metal inter-level dielectric layers 23 over the device components 21, 22 by chemical vapor deposition (CVD), plasma-enhanced chemical vapor deposition (PECVD), physical vapor deposition (PVD), atomic layer deposition (ALD), or any combination thereof to a thickness of approximately 500-10000 Angstroms, though other thicknesses may also be used. As will be appreciated, the inter-level dielectric layer 23 may be formed from one or more constituent layers, such as by depositing a layer of dielectric material. Other component layer materials and/or processes may be used to form the inter-level dielectric layer 23 above the substrate 20, such as by depositing or otherwise forming an oxide layer formed from tetraethylorthosilicate (TEOS), borophosphosilicate glass (BPSG), etc. After the inter-level dielectric layer 23 is formed to completely cover the top and sides of the device components 21, 22, the layer 23 is polished into a planarized dielectric layer, as illustrated in FIG. 2. In particular, a chemical mechanical polishing step may be used to polish the inter-level dielectric layers 23, though other etch processes may be used to planarize the dielectric layer 23.

A contact opening 24 is etched through the ILD 23 to expose an underlying device component, such as a source/drain region formed in a substrate 20. Though it will be appreciated that the contact opening 24a may also be formed in the ILD 23 to expose a gate electrode in a device component 21, 22, the description provided herein will focus on the contact opening 24 that exposes the active region of a substrate 20. For current state-of-the-art circuit designs, the contact opening 24 has a width of approximately 1000-3000 Angstroms, more preferably less than approximately 1500 Angstroms, resulting in an aspect ratio (height:width) of greater than about 3:1, and more preferably at least about 6:1 with floating gate NVM devices, though aspect ratios in future generation process technologies will be still higher. Any desired photolithography and/or selective etch techniques can be used to form the contact opening 24 that exposes a selected contact region over the source/drain region in the substrate 20, though a contact region 24a may also be located over a gate electrode. For example, the contact opening 24 may be formed by depositing and patterning a protective mask layer over the ILD 23 in which a contact hole is defined (not shown), and then anisotropic etching (e.g., reactive ion etching) the exposed ILD 23 to form the contact opening 24 with an etch process that produces contact opening sidewalls. In another embodiment, a three stage etch process is used which removes selected portions of a protective mask layer (not shown) formed over the ILD 23, the planarized ILD 23, and an etch stop layer (not shown) formed over a selected contact region (and/or gate electrode). As a preliminary step, a layer of photoresist (not shown) may be applied and patterned directly on the protective cap layer, though multi-layer masking techniques may also be used to define the location of the contact opening 24. The exposed portions of the protective cap layer, the ILD layer 23, and the etch stop layer are then removed by using the appropriate etchant processes to etch a contact opening 24, such as an anisotropic reactive ion etching (RIE) process using O₂, N₂, or a fluorine-containing gas. For example, an etch process that is selective for the material of the ILD 23 (such as an Argon, CHF₃, or CF₄ chemistry that is used to etch carbon-doped oxide film) is used to etch through the exposed portion of the ILD 23. One or more additional etch and/or ash processes may be used to remove any remaining layers.

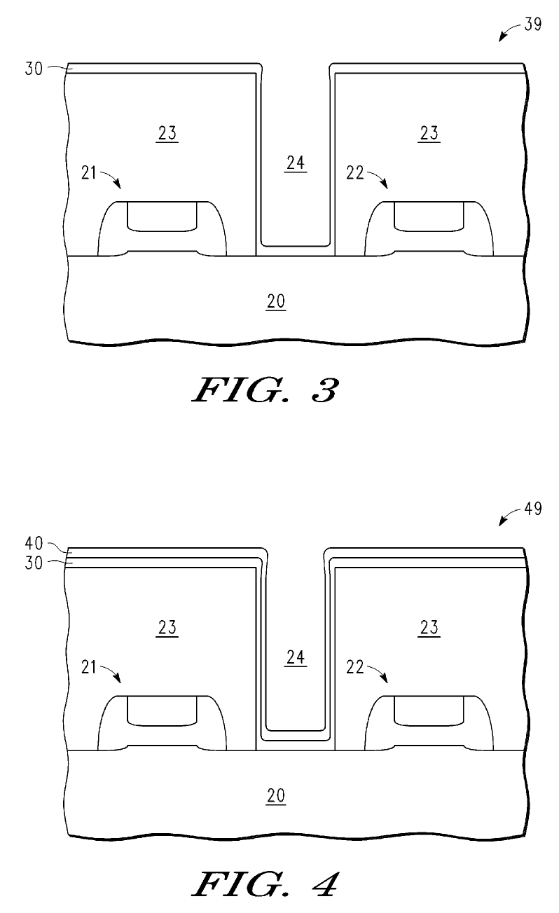

FIG. 3 illustrates processing of a semiconductor device 39 subsequent to FIG. 2 after an initial contact layer 30 is integrally formed in at least the contact opening 24. In a selected embodiment, the initial contact layer 30 is formed by depositing a layer of tantalum or titanium. The deposited contact layer 30 acts to lower the contact resistance by reducing native oxide formed on an underlying silicide layer. The initial contact layer 30 may be deposited over the semiconductor device 39 and onto the sidewalls and floor of the contact opening 24 using a physical vapor deposition (PVD) process after a sputtering clean process, though other deposition processes may be used, such as CVD, PECVD, ALD, or any combination thereof. In a selected embodiment, the initial contact layer 30 is formed by depositing titanium or tantalum to a thickness of approximately 10-1000 Angstroms, and more preferably between about 50-300 Angstroms, though other thicknesses may also be used. As will be appreciated, the sidewall thickness of the initial contact layer 30 will be thinner than the thickness of the initial contact layer measured at the top surfaces of the contact opening 24. While the initial contact layer 30 may be formed with titanium, any suitable material may be used which reduces the contact resistance for the underlying silicide layer and/or reduces the native oxide formed on the underlying silicide layer, so long as the material has a composition suitable for providing an adhesive contact function between the underlying silicide and subsequently formed titanium nitride layer.

FIG. 4 illustrates processing of a semiconductor device 49 subsequent to FIG. 3 after a first diffusion barrier layer 40 is integrally formed over the initial contact layer 30 in at least the contact opening 24. In a selected embodiment, the first diffusion barrier layer 40 is formed by depositing a layer of titanium nitride. The deposited titanium nitride acts as a copper diffusion barrier to prevent a copper from diffusing through to the underlying contact layer 30 and silicide, and may also act as a fluorine barrier to prevent a volatile fluorine reaction from occurring during a subsequent formation of a tungsten barrier layer (described below). The titanium nitride layer 40 may be deposited over the initial contact layer 30 and onto the sidewalls and floor of the contact opening 24 by CVD, PECVD, PVD, ALD, or any combination thereof to a sidewall thickness of approximately 25-1000 Angstroms, and more preferably between about 50-100 Angstroms, though other thicknesses may also be used. Again, the sidewall thickness of the first diffusion barrier layer 40 will be thinner than the thickness of the first diffusion barrier layer 40 measured at the top surfaces of the contact opening 24. And while the first diffusion barrier layer 40 may be formed with titanium nitride, any suitable material may be used which acts as a copper and/or fluorine barrier, so long as the material has a composition suitable for providing an adhesive function between the underlying contact layer 30 and subsequently formed tungsten layer.

FIG. 5 illustrates processing of a semiconductor device 59 subsequent to FIG. 4 after a seed layer 50 is integrally formed over the first diffusion barrier layer 40 in at least the contact opening 24. In a selected embodiment, the seed layer 50 is a highly conductive metal (such as a nucleation layer of tungsten) that serves as a metal seed layer during a subsequent direct copper electroplating step. However, it will be appreciated that the metal seed layer 50 may include trace amounts of impurities, including nitrogen. In various embodiments, the tungsten seed layer 50 may be formed with an amorphous or small grain structure to act as a copper diffusion barrier to prevent subsequently-formed copper from diffusing through to the underlying layer(s). For example, the tungsten barrier layer may be formed with an amorphous or small grain structure by depositing tungsten onto the sidewalls and floor of the contact opening 24 using any deposition process, such as a physical vapor deposition (PVD) process (e.g., reactive sputtering). As will be appreciated, other deposition processes may be used to form the tungsten barrier layer, such as using a silicon-containing gas (e.g., silane or dichlorosilane) that decomposes a tungsten-containing source (e.g., WF₆) with or without hydrogen (e.g., WF₆+SiH₄). As will be appreciated, as the amount of silane increases in the tungsten formation process, the crystalline structure of the tungsten becomes more amorphous, thereby providing a more effective diffusion barrier against metal ions, such as copper which can not readily diffuse through the smaller grain boundaries of the amorphous or small grain tungsten layer. However deposited, the tungsten seed/barrier layer 50 may be deposited over the titanium nitride layer 40 and onto the sidewalls and floor of the contact opening 24 to a sidewall thickness of approximately 25-1000 Angstroms, though other thicknesses may also be used, provided that the tungsten does not fill the contact opening. As will be appreciated, the sidewall thickness of the tungsten seed/barrier layer 50 will be thinner than the thickness of the tungsten seed/barrier layer 50 measured at the top surfaces of the contact opening 24. And while the seed/barrier layer 50 may be formed with tungsten, any suitable material may be used, so long as the material has a composition suitable for providing a seed layer for a subsequent metal electroplating process and/or for providing a barrier function to reduce or prevent diffusion of subsequently formed metal to the underlying layers 30, 40.

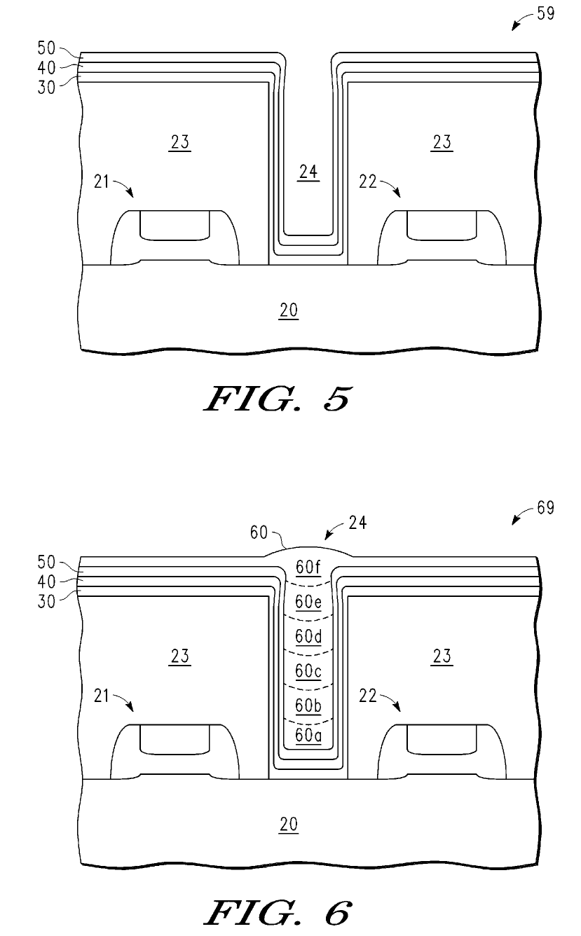

FIG. 6 illustrates processing of a semiconductor device 69 subsequent to FIG. 5 after the contact opening 24 is filled from the bottom up by electroplating a contact metal plug material 60 onto the seed layer 50. For high aspect ratio contact fills, a bottom up fill is desirable for the bulk of the contact fill to eliminate coring or voids in the plug. When the seed layer 50 is formed in a sputtering chamber, the semiconductor device 69 is removed from the sputtering chamber in preparation for electroplating metal upon the seed layer 50. Where the seed layer 50 is formed with substantially pure tungsten, an native oxide that readily forms on the tungsten through exposure to atmospheric oxidants can be pre-cleaned prior to electroplating by using a conventional pre-cleaning process (such as a dilute hydrofluoric acid (HF) dip) or by applying an electroplating solution to remove the native oxide (such as by applying a reverse polarity potential to the electroplating solution). After removal of the native oxide from the seed layer 50, copper layers 60a-f are deposited to fill the contact opening 24 from the bottom up with electroplated copper 60. By using a copper electroplate process, a first copper layer 60a is formed on the bottom of the contact opening 24, following by a successive copper layers 60b-60f. In a selected embodiment, copper plating is conducted using any desired copper electroplating process. The copper electroplating process continues until the entire contact opening 24 is filled or overflowed with copper 60, at which point the electroplated copper 60 may be annealed. By using an electroplate process to fill the contact opening 24 from the bottom up, voids or cores in the layers 60a-60f are eliminated or at least reduced, thereby providing a low resistivity contact plug layer 60. In addition, the electroplate process causes the copper ions to plate the inner surfaces of the contact opening 24 such that the barrier layers 40, 50 prevent the copper ions from readily diffusing through to the underlying contact layer 30, ILD 23 and/or silicide/substrate 20.

Together, the initial contact layer 30, diffusion barrier layer 40 and seed/barrier layer 50 form a barrier/seed layer which provides a contact adhesive function and reduces native oxide at the underlying silicide surface. In addition, the barrier/seed layer provides one or more diffusion barrier functions for the contact plug. In yet another function, the barrier/seed layer provides a seed layer function for the electroplated copper 60. While the initial contact layer 30, diffusion barrier layer 40 and seed/barrier layer 50 can be formed in a single process chamber to increase process efficiency, preferably in a continuous process, the layers may also be formed in two or more process chambers.

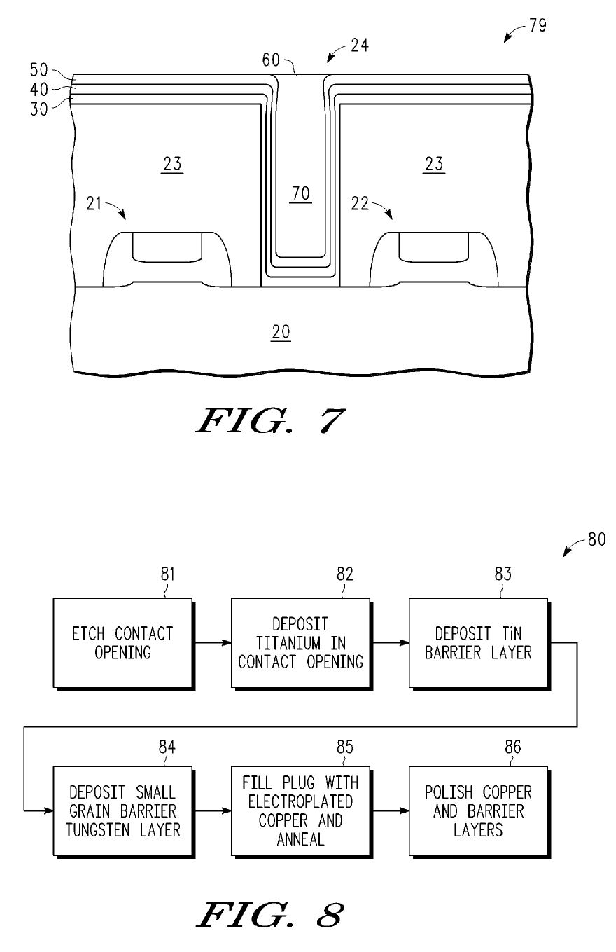

FIG. 7 illustrates processing of a semiconductor device 79 subsequent to FIG. 6 after a chemical mechanical polish step is used to remove the excess conductive material from the contact metal layer 60 up to and/or including at least part of the underlying barrier layers 30, 40, 50 formed over the ILD 23, thereby forming a contact plug 70. In a selected embodiment, a chemical mechanical polish (CMP) process is used to polish back the contact metal layer 60 until it is substantially co-planar with the underlying barrier layers 30, 40, 50 formed over the ILD 23. By using a timed or end point CMP process, the excess metal is removed, leaving only the metal plugs 70 in the contact hole 24. As will be appreciated, the CMP step may also remove one or more of the underlying barrier layers 30, 40, 50 formed over the ILD 23 to leave isolated a contact plug 70 within the contact opening 24. In a selected embodiment, the upper portions of the copper layer 60, tungsten seed layer 50 and glue layers 30, 40 are polished in the field regions. In addition or in the alternative, other etchback processes may be used to planarized the contact plug 70.

As will be appreciated, additional processing steps may be used to complete the fabrication of the semiconductor device 79 into a functioning device. In addition to various front end processing steps (such as sacrificial oxide formation, stripping, isolation region formation, gate electrode formation, extension implant, halo implant, spacer formation, source/drain implant, annealing, silicide formation, and polishing steps), additional backend processing steps may be performed, such as forming multiple levels of interconnect(s) that are used to connect the device components in a desired manner to achieve the desired functionality. Thus, the specific sequence of steps used to complete the fabrication of the device components may vary, depending on the process and/or design requirements.

FIG. 8 is a flow diagram illustrating a process 80 for forming a void-free contact plug. As shown, the process begins by forming or etching a contact opening through an insulating layer (step 81), thereby exposing an underlying substrate, gate or electrode contact region. Following contact formation 81, a barrier/seed layer is formed by sequentially depositing a contact layer, a diffusion barrier layer and a seed layer within the contact opening. First, a layer of titanium is deposited in the contact opening (step 82) which is used to reduce native oxide on the underlying silicide, thereby reducing contact resistance in the contact plug. Subsequently, a layer of titanium nitride is deposited in the contact opening over the titanium layer (step 83) which acts as a barrier layer to protect the underlying layers from fluorine and/or copper diffusion. Subsequently, a metal layer (e.g., tungsten) is deposited in the contact opening over the titanium nitride layer (step 84) which acts as a metal seed layer for a subsequent copper electroplate layer. When the metal seed layer is formed by depositing a tungsten layer having an amorphous or small grain crystalline structure, the tungsten layer acts as a barrier layer to protect the underlying layers from copper diffusion. Thus, while the barrier/seed layer may be formed with a single fabrication process conducted in situ in the same process chamber, it will be understood that the barrier/seed layer may also be formed in separate process phases. After the metal seed layer is formed 84 over the sub-layers, the structure may be optionally precleaned (not shown) and then the plug is formed by electroplating an appropriate metal to fill the contact opening (step 85), thereby forming a void-free contact plug. For example, the plug may be formed with copper or other metal that is electroplated directly onto the tungsten layer and then annealed. Subsequently, the copper and seed/barrier layers are planarized with a polish step (step 86), after which standard BEOL processing may be used to complete the device.

By now it should be appreciated that there has been provided a method for forming a contact plug in a semiconductor structure. Under one form of the method, a semiconductor structure is provided over which a dielectric layer (e.g., an inter-level dielectric layer) is formed. After a contact opening is formed through the dielectric layer to expose a contact region in an underlying semiconductor device, an initial contact layer (e.g., titanium or tantalum) is deposited into the contact opening. Subsequently, a barrier layer (e.g., titanium nitride) is deposited on the initial contact layer and into the contact opening, followed subsequently by the deposition of a metal seed layer (e.g., tungsten) on the barrier layer and into the contact opening, where the metal seed layer may have a substantially amorphous or small grain crystalline structure (e.g., nanocrystals that are no greater than approximately 50 Angstroms). The metal seed layer may be formed by depositing a tungsten layer using a physical vapor deposition process to sputter deposit a layer of tungsten on the barrier layer and into the contact opening, or by CVD using a silane or dichlorosilane decomposition of a tungsten-containing source (e.g., WF₆) to deposit a layer of tungsten on the barrier layer and into the contact opening. After the contact, barrier and seed layers are formed in the contact opening, the contact opening is filled up from a bottom surface of the contact opening with a metal material, such as by electroplating copper on the metal seed layer to fill the contact opening without forming a void. Once the contact opening is filled, any excess conductive material may be removed from outside the contact opening by polishing the semiconductor structure down to at least the metal seed layer, such as by using a CMP process to remove any portion of the second metal material, metal seed layer, barrier layer and initial contact layer formed over the dielectric layer and outside the contact opening.

In another form, there is provided a method of forming a conductive structure in an opening in a partially fabricated integrated circuit. As described, a contact opening is formed through a dielectric layer to expose a contact region in an underlying semiconductor device. In the contact opening, an initial metal layer is deposited using a physical vapor deposition process (e.g., by sputtering titanium or tantalum) so that the initial metal layer overlays the side and bottom surfaces of the contact opening while leaving the contact opening substantially open. Subsequently, a metal nitride layer is deposited over the initial metal layer in the contact opening (e.g., by depositing titanium nitride by CVD) so that the metal nitride layer overlays the side and bottom surfaces of the contact opening while leaving the contact opening substantially open. Over the metal nitride layer, an amorphous or small grained metal seed layer is deposited in the contact opening so that the amorphous or small grained metal seed layer overlays the side and bottom surfaces of the contact opening while leaving the contact opening substantially open. The amorphous or small grained metal seed layer may be formed by depositing a tungsten layer in the contact opening using a physical vapor deposition process, or by depositing a tungsten layer in the contact opening using a silane or dichlorosilane decomposition of WF₆. With these layers in place, copper is electroplated onto at least the side and bottom surfaces of the contact opening to fill the contact opening. Subsequently, a chemical mechanical polish process is applied to remove any portion of the electroplated copper, amorphous or small grained metal seed layer, metal nitride layer and initial metal layer formed outside the contact opening.

In yet another form, there is provided a method of forming a contact plug in a semiconductor structure by first forming a contact opening through a dielectric layer to expose a contact region in an underlying semiconductor device. In the contact opening, a titanium contact layer is deposited, followed by the deposition of a barrier layer onto the titanium contact layer and into the contact opening. Subsequently, a metal seed layer is deposited on the barrier layer and into the contact opening. In an example embodiment, the metal seed layer is formed using a silicon-containing gas that decomposes a tungsten-containing source to deposit a layer of amorphous tungsten on the barrier layer and into the contact opening. With these layers in place, the contact opening is filled up from a bottom surface of the contact opening with a metal material, such as by electroplating copper on the metal seed layer to fill the contact opening without forming a void. Any excess conductive material is removed from outside the contact opening by polishing the semiconductor structure down to at least the metal seed layer.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. For example, the methodology of the present invention may be applied using materials other than expressly set forth herein. In addition, the invention is not limited to any particular type of integrated circuit described herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A method of forming a contact plug in a semiconductor structure, comprising:
providing a semiconductor structure;
forming a dielectric layer over the semiconductor structure;
forming a contact opening through the dielectric layer to expose a contact region in an underlying semiconductor device;
depositing an initial contact layer into the contact opening;
depositing a barrier layer on the initial contact layer and into the contact opening;
depositing a tungsten seed layer on the barrier layer and into the contact opening;
filling the contact opening up from a bottom surface of the contact opening with a metal material; and
removing any excess conductive material from outside the contact opening by polishing the semiconductor structure down to at least the tungsten seed layer.

2. The method of claim 1, where depositing an initial contact layer comprises depositing a layer of titanium or tantalum into the contact opening.

3. The method of claim 1, where depositing a barrier layer comprises depositing a layer of titanium nitride on the initial contact layer and into the contact opening.

4. The method of claim 1, where depositing the tungsten seed layer comprises depositing a layer of amorphous or small grained tungsten on the barrier layer and into the contact opening.

5. The method of claim 4, where depositing a layer of amorphous or small grained tungsten comprises using a physical vapor deposition process to sputter deposit a layer of amorphous or small grained tungsten on the barrier layer and into the contact opening.

6. The method of claim 4, where depositing a layer of amorphous or small grained tungsten comprises using a silicon-containing gas that decomposes a tungsten-containing source to deposit a layer of amorphous or small grained tungsten on the barrier layer and into the contact opening.

7. The method of claim 1, where the tungsten seed layer has an amorphous or small grain crystalline structure.

8. The method of claim 1, where filling the contact opening comprises electroplating copper on the tungsten seed layer to fill the contact opening without forming a void.

9. The method of claim 1, wherein polishing the semiconductor structure comprises using a chemical mechanical polish process to remove any portion of the metal material, tungsten seed layer, barrier layer and initial contact layer formed over the dielectric layer and outside the contact opening.

10. A method of forming a conductive structure in an opening in a partially fabricated integrated circuit, comprising:
forming a contact opening through a dielectric layer to expose a contact region in an underlying semiconductor device;
depositing an initial metal layer in the contact opening using a physical vapor deposition process, the initial metal layer overlaying side and bottom surfaces of the contact opening while leaving the contact opening substantially open;
depositing a metal nitride layer over the initial metal layer in the contact opening, the metal nitride layer overlaying side and bottom surfaces of the contact opening while leaving the contact opening substantially open;
depositing an amorphous metal seed layer over the metal nitride layer in the contact opening, the amorphous metal seed layer overlaying side and bottom surfaces of the contact opening while leaving the contact opening substantially open; and
electroplating copper onto at least the side and bottom surfaces of the contact opening to fill the contact opening.

11. The method of claim 10, where depositing an initial metal layer comprises sputtering titanium or tantalum.

12. The method of claim 10, where depositing a metal nitride layer comprises depositing titanium nitride.

13. The method of claim 10, where depositing a metal nitride layer comprises depositing titanium nitride by chemical vapor deposition.

14. The method of claim 10, where depositing an amorphous metal seed layer comprises depositing a tungsten layer in the contact opening using a physical vapor deposition process.

15. The method of claim 10, where depositing an amorphous metal seed layer comprises depositing a tungsten layer in the contact opening using a silane decomposition of WF₆.

16. The method of claim 10, where depositing an amorphous metal seed layer comprises depositing a tungsten layer in the contact opening using a dichlorosilane decomposition of WF₆.

17. The method of claim 10, further comprising applying a chemical mechanical polish process to remove any portion of the electroplated copper, amorphous metal seed layer, metal nitride layer and initial metal layer formed outside the contact opening.

18. A method of forming a contact plug in a semiconductor structure, comprising:
forming a contact opening through a dielectric layer to expose a contact region in an underlying semiconductor device;
depositing a titanium contact layer into the contact opening;
depositing a barrier layer on the titanium contact layer and into the contact opening;
depositing a metal seed layer on the barrier layer and into the contact opening;
filling the contact opening up from a bottom surface of the contact opening with a metal material; and
removing any excess conductive material from outside the contact opening by polishing the semiconductor structure down to at least the metal seed layer.

19. The method of claim 18, where depositing a metal seed layer comprises using a silicon-containing gas that decomposes a tungsten-containing source to deposit a layer of amorphous tungsten on the barrier layer and into the contact opening.

20. The method of claim 18, where filling the contact opening comprises electroplating copper on the metal seed layer to fill the contact opening without forming a void.
